(19) United States
(12) Patent Application Publication
(10) Pub. No.: US 2025/0141189 A1
(43) Pub. Date: May 1, 2025

(54) OPTICAL SEMICONDUCTOR DEVICE

(71) Applicant: Mitsubishi Electric Corporation, Tokyo (JP)

(72) Inventors: Ayumi FUCHIDA, Tokyo (JP); Go SAKAINO, Tokyo (JP)

(73) Assignee: Mitsubishi Electric Corporation, Tokyo (JP)

(21) Appl. No.: 18/692,698

(22) PCT Filed: Jan. 27, 2022
(86) PCT No.: PCT/JP2022/003098

§ 371 Date: Mar. 15, 2024

(51) Int. Cl. H01S 5/30; H01S 5/02; H01S 5/042; H01S 5/22; H01S 5/42

(52) U.S. Cl. CPC H01S 5/3013; H01S 5/0206; H01S 5/0421; H01S 5/2202; H01S 5/42

(57) ABSTRACT

Active portions (A) and passive portions (B) are alternately arranged along a first direction on a semiconductor substrate (1) of a first conductive type. An electrode (2) is provided on the active portion (A). The active portion (A) includes an active layer (4), a second conductive type cladding layer (5), and a second conductive type contact layer (6) that are stacked in order on the semiconductor substrate (1). The active portion (A) has a resonator structure sandwiched between a front end surface (8) and a rear end surface (9) in a second direction perpendicular to the first direction. The second conductive type contact layer (6) in the active portion (A) is in contact with the electrode (2). The passive portion (B) includes the second conductive type contact layer (6) and a first conductive type layer (7) provided on the second conductive type contact layer (6).

### FIELD

The present disclosure relates to an optical semiconductor device.

### BACKGROUND

An optical semiconductor device that has a junction-down-mounted laser-array chip, on which a plurality of end-surface emission lasers are arranged in an array in a lateral direction, has been developed. In a prior-art structure, to block current paths that pass through areas other than a light emitting point, it has been a practice to cover passive portions other than a contact opening where current injection is achieved with an insulation film.

A semiconductor laser has been proposed, in which an n-type InP layer is provided on a p-type InGaAsP contact layer in a vicinity of an end surface to prevent a current from being injected into the vicinity of the end surface (for example, see PTL 1). In the semiconductor laser, however, a current injection area and a non-current injection area are arranged between a front end surface and a rear end surface. Therefore, the semiconductor laser is not a laser array chip including a plurality of end-surface emission lasers arranged in an array in a lateral direction.

### CITATION LIST

### Patent Literature

[PTL 1] JP 2003-152274 A

### SUMMARY OF THE INVENTION

### Problems to be Solved by the Invention

To fabricate a conforming laser array chip as a whole, continuity of a prescribed number of conforming single lasers is necessary. Therefore, in a case of a defective single laser is generated, the conforming laser array chip is cut out at an optional position so as to eliminate the defective single laser, which makes it possible to a yield. However, when all passive portions are covered with the hard insulation film as in the prior-art structure, it is difficult to perform cleavage through the insulation film. Further, without the insulation film provided on the passive portions, solder flows into a portion not covered with the insulation film when junction-down mounting is performed. This generates an unexpected current path, and a mounting method is accordingly limited.

An object of the present disclosure, which has been made to solve the above-described issues, is to provide an optical semiconductor device that can prevent a current from flowing through the passive portions even in a case where the junction-down mounting is performed, and enables chip cutout by cleavage at an optional passive portion.

### Solution to Problem

An optical semiconductor device according to the present disclosure includes: a semiconductor substrate of a first conductive type; active portions and passive portions alternately arranged along a first direction on the semiconductor substrate; and an electrode provided on the active portion, wherein the active portion includes an active layer, a second conductive type cladding layer, and a second conductive type contact layer that are stacked in order on the semiconductor substrate, the active portion has a resonator structure sandwiched between a front end surface and a rear end surface in a second direction perpendicular to the first direction, the second conductive type contact layer in the active portion is in contact with the electrode, and the passive portion includes the second conductive type contact layer and a first conductive type layer provided on the second conductive type contact layer.

### Advantageous Effects of Invention

In the present disclosure, the first conductive type layer is provided between the second conductive type contact layer and the electrode in the passive portion. Therefore, even when the junction-down mounting is performed, it is possible to prevent the current from flowing through the passive portion. In addition, it is unnecessary to cover the surfaces of the passive portion with hard insulation films made of SiO₂ or the like. This makes it possible to cut out a chip by cleavage at an optional passive portion.

### BRIEF DESCRIPTION OF THE DRAWINGS

FIG. 1 is a cross-sectional view illustrating an optical semiconductor device according to Embodiment 1.

FIG. 2 is a cross-sectional view taken along line I-II in FIG. 1.

FIG. 3 is a cross-sectional view illustrating a state where the optical semiconductor device according to Embodiment 1 is junction-down mounted.

FIG. 4 is a cross-sectional view illustrating an optical semiconductor device according to Embodiment 2.

FIG. 5 is a cross-sectional view illustrating a state where the optical semiconductor device according to Embodiment 2 is junction-down mounted.

FIG. 6 is a cross-sectional view illustrating an optical semiconductor device according to Embodiment 3.

FIG. 7 is a cross-sectional view illustrating a state where the optical semiconductor device according to Embodiment 3 is junction-down mounted.

FIG. 8 is a perspective view illustrating an optical semiconductor device according to Embodiment 4.

FIG. 9 is a cross-sectional view taken along line I-II in FIG. 8.

FIG. 10 is a perspective view illustrating an optical semiconductor device according to Embodiment 5.

FIG. 11 is a cross-sectional view taken along line I-II in FIG. 10.

### DESCRIPTION OF EMBODIMENTS

An optical semiconductor device according to the embodiments of the present disclosure will be described with reference to the drawings. The same components will be denoted by the same symbols, and the repeated description thereof may be omitted.

### Embodiment 1

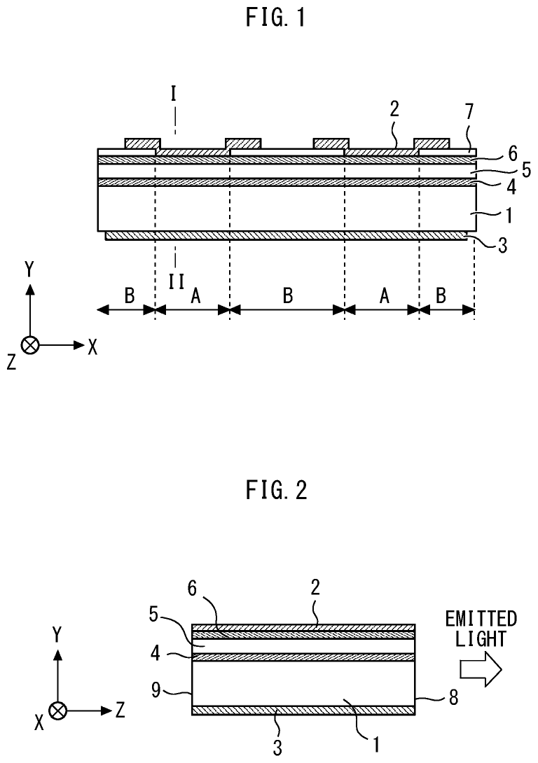

FIG. 1 is a cross-sectional view illustrating an optical semiconductor device according to Embodiment 1. A horizontal direction perpendicular to a laser resonator is denoted by X, a stacking direction of semiconductor layers is denoted by Y, and a laser resonator direction through which light propagates is denoted by Z. FIG. 1 illustrates an XY plane, and FIG. 2 illustrates a YZ plane. In the present embodiment, a case where the optical semiconductor device is an end-surface emission stripe laser array is described; however, the optical semiconductor device is not limited thereto. Similar effects can be achieved by an LED, an optical amplifier, an optical modulator, or the like as long as the optical semiconductor device is of a waveguide type.

On an n-type InP substrate 1, active portions A and passive portions B having a depth in the Z direction and forming a stripe structure are alternately arranged in an array along the X direction. The optical semiconductor device includes two or more active portions A. A p-type electrode 2 is provided on the active portions A and the passive portions B. An n-type electrode 3 is provided on a lower surface of the n-type InP substrate 1.

Each of the active portions A includes an active layer 4, a p-type InP cladding layer 5, and a p-type InGaAs contact layer 6 that are stacked in order on the n-type InP substrate 1. The p-type InGaAs contact layer 6 of the active portions A exposed as the outermost surface is in contact with the p-type electrode 2.

Each of the passive portions B includes the active layer 4, the p-type InP cladding layer 5, the p-type InGaAs contact layer 6, and an n-type InP layer 7 that are stacked in order on the n-type InP substrate 1. The passive portions B are different from the active portions A in that the n-type InP layer 7 is provided between the p-type InGaAs contact layer 6 and the p-type electrode 2. The passive portions B are adjacent to the active portions A. The p-type electrode 2 and the n-type electrode 3 in each of the active portions A may be within a range of each of the active portions A, or may protrude to the adjacent passive portions B.

The n-type InP substrate 1 includes a (001) plane as a principal surface, is doped with Si, and has a carrier concentration of 4E+18 cm⁻³. The active layer 4 is made of an AlGaInAs-based or InGaAsP-based material, and has a thickness of 0.2 um. The p-type InP cladding layer 5 is doped with Zn, and has a carrier concentration of 1E+18 cm⁻³ and a thickness of 2 um. The p-type InGaAs contact layer 6 has a carrier concentration of 1E+19 cm⁻³ and a thickness of 0.3 um. The n-type InP layer 7 has a carrier concentration of 1E+18 cm⁻³ and a thickness of 0.1 um. An n-type InP cladding layer having a carrier concentration of 4E+18 cm⁻³ and a thickness of 0.5 um may be sandwiched between the n-type InP substrate 1 and the active layer 4. The active layer 4 may include a multiple quantum well structure or a quantum dot structure. The p-type InGaAs contact layer 6 may be a combined structure of p-type InGaAs and p-type InGaAsP. A p-type InP layer having a carrier concentration of 1E+18 cm⁻³ and a thickness of 0.1 um may be sandwiched between the p-type InGaAs contact layer 6 and the n-type InP layer 7.

FIG. 2 is a cross-sectional view taken along line I-II in FIG. 1. Each of the active portions A has a resonator structure sandwiched in the Z direction between a front end surface 8 and a rear end surface 9 both parallel to the XY plane.

Subsequently, a method of manufacturing the optical semiconductor device according to the present embodiment is described. First, the active layer 4, the p-type InP cladding layer 5, the p-type InGaAs contact layer 6, and the n-type InP layer 7 are crystal-grown in order on the n-type InP substrate 1 by using a semiconductor-film growing apparatus such as MOCVD or MBE. After the stacked-layer structure is grown, a photoresist is applied onto the n-type InP layer 7 as the outermost surface. Thereafter, stripe-shaped openings extending in a direction are formed in the photoresist in regions corresponding to the active portions A. A width of each of the openings is within a range from 0.5 um to 20 um, and an interval between the openings in the X direction is within a range from 100 um to 300 um; however, the width and the interval are not limited to these ranges.

Thereafter, the n-type InP layer 7 exposed from the openings of the photoresist is removed using hydrochloric acid to expose the p-type InGaAs contact layer 6 below the n-type InP layer 7. Only the InP layer can be selectively etched because InGaAs is low in etching rate to the hydrochloric acid as compared with InP. After the photoresist is removed, films of a metal simple substance containing Au, Pt, Zn, Ge, Ni, Ti, and the like or films of a mixture of these metals are formed on the p-type InGaAs contact layer 6 and below the n-type InP substrate 1, to form the p-type electrode 2 and the n-type electrode 3. To form the metal film, vapor deposition or a sputtering apparatus is used. Next, the front end surface 8 and the rear end surface 9 each formed of a (110) plane are formed by cleavage. Finally, the passive portions B in which the n-type InP layer 7 is exposed as the outermost surface are cleaved in the direction to manufacture a laser array in which an optional number of stripe lasers are arranged. The laser array can be manufactured by one-time crystal growth. Therefore, the laser array can be efficiently manufactured at a low cost.

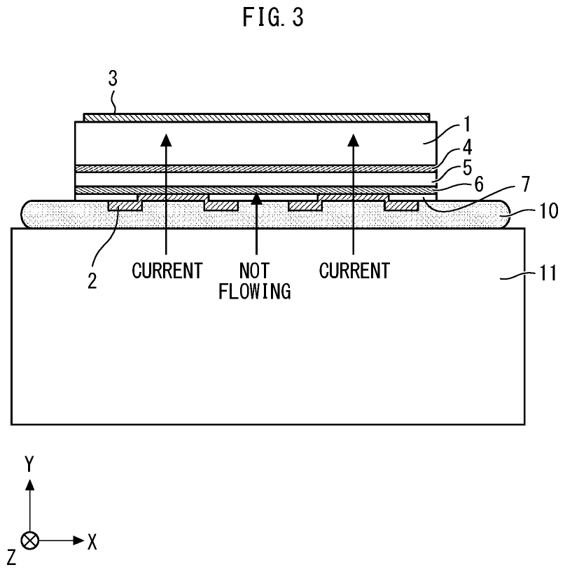

FIG. 3 is a cross-sectional view illustrating a state where the optical semiconductor device according to Embodiment 1 is junction-down mounted. The optical semiconductor device is junction-down mounted on a sub-mount 11 with solder 10 while the p-type electrode 2 of the optical semiconductor device is directed downward. The junction-down mounting is excellent in heat dissipation because the active layer 4 and the sub-mount 11 are brought close to each other, and is excellent in Y-direction positional controllability of the active layer 4 because a distance from the sub-mount 11 to the active layer 4 can be determined by a crystal growth film thickness.

To operate the optical semiconductor device according to Embodiment 1, a forward-direction voltage is applied to the p-type electrode 2 and the n-type electrode 3. As a result, in the active portions A, holes are supplied from the p-type InGaAs contact layer 6 to the active layer 4 through the p-type InP cladding layer 5, and electrons are supplied from the n-type InP substrate 1 to the active layer 4. When the electrons and the holes are recombined in the active layer 4, optical gain and light emission can be obtained. On the other hand, even when the solder 10 is adhered to the n-type InP layer 7 as the outermost surface of the passive portions B and the voltage is applied, no current flows through the passive portions B because a reverse-direction voltage is applied between the n-type InP layer 7 and the p-type InGaAs contact layer 6. At this time, when the n-type InP layer 7 is thin, the n-type InP layer 7 cannot stand application of the reverse-direction voltage, and the current may flow through the passive portions B. Therefore, the n-type InP layer 7 desirably has a thickness of 50 nm or more.

As described above, in the active layer 4 in the active portions A, the gain is generated by the current injection, whereas in the passive portions B, the gain is not generated. Therefore, light generated by recombination of the electrons and the holes propagates only through the active portions A. The light obtains a gain while reciprocating in the resonator sandwiched between the front end surface 8 and rear end surface 9 in the Z direction, to realize laser oscillation, and is emitted from the front end surface 8. A length of the resonator sandwiched between the front end surface 8 and the rear end surface 9 varies depending on applications, and can have a value within a wide range from 0.15 mm to 4 mm in general; however, the length of the resonator is not limited to the range.

As described above, in the present embodiment, the n-type InP layer 7 is provided between the p-type InGaAs contact layer 6 and the p-type electrode 2 in the passive portions B. Therefore, even when the junction-down mounting is performed, it is possible to prevent the current from flowing through the passive portions B. In addition, it is unnecessary to cover the surfaces of the passive portions B with hard insulation films made of SiO₂ or the like. This makes it possible to cut out a chip by cleavage at an optional passive portion B. Accordingly, the laser array can be fabricated while selecting a region where conforming lasers are arranged.

### Embodiment 2

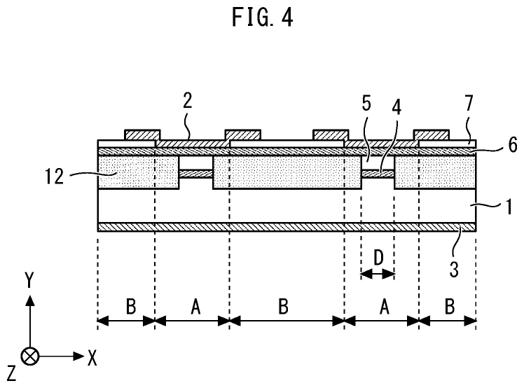

FIG. 4 is a cross-sectional view illustrating an optical semiconductor device according to Embodiment 2. In the present embodiment, a case where the optical semiconductor device is an end-surface emission buried laser array is described; however, the optical semiconductor device is not limited thereto. Similar effects can be achieved by an LED, an optical amplifier, an optical modulator, or the like as long as the optical semiconductor device is of a waveguide type.

Etching extends from the p-type InP cladding layer 5 up to below the active layer 4, and ridge structures D each extending in the Z direction are accordingly provided. A buried layer 12 is provided so as to cover side surfaces of the ridge structures D up to a position higher than the active layer 4. The buried layer 12 is made of a semi-insulation material such as InP doped with Ru or Fe, but may be obtained by combining a plurality of semiconductor layers different in carrier concentration or polarity. For example, the buried layer 12 is made of InP doped with Fe having a carrier concentration of 5E+16 cm³. A width of each of the ridge structures D is within a range from 0.5 um to 2.0 um; however, the width of each of the ridge structures D is not limited to the range. The p-type InGaAs contact layer 6 is provided on the ridge structures D and the buried layer 12. Each of the passive portions B includes the buried layer 12, the p-type InGaAs contact layer 6, and the n-type InP layer 7 that are stacked in order on the n-type InP substrate 1. A p-type InP layer may be provided between the p-type InP cladding layer 5 as the outermost surface in the ridge structures D and the p-type InGaAs contact layer 6 and between the buried layer 12 and the p-type InGaAs contact layer 6. The other structure is similar to the structure in Embodiment 1.

Subsequently, a method of manufacturing the optical semiconductor device according to the present embodiment is described. First, the active layer 4 and the p-type InP cladding layer 5 are crystal-grown in order on the n-type InP substrate 1. Thereafter, a stripe-shaped mask pattern extending in the direction is formed. A width of each of stripe-shaped masks is within a range from 0.5 um to 2 um in most cases; however, the width is not limited to the range. Thereafter, etching is performed up to below the active layer 4 to form the ridge structures D. Next, the buried layer 12 is grown to cover the side surfaces of the ridge structures D up to above the active layer 4. After the mask is removed, the p-type InGaAs contact layer 6 and the n-type InP layer 7 are grown on the buried layer 12 and the p-type InP cladding layer 5 as the outermost surface of the ridge structures D. The crystal growth step is thus completed. A subsequent step is similar to the step in Embodiment 1.

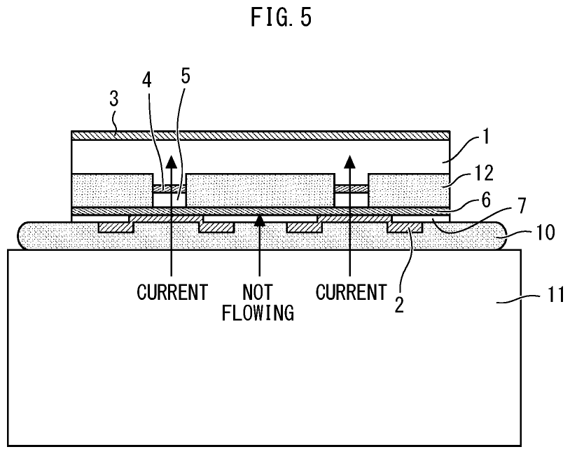

FIG. 5 is a cross-sectional view illustrating a state where the optical semiconductor device according to Embodiment 2 is junction-down mounted. The optical semiconductor device is junction-down mounted on the sub-mount 11 with the solder 10 while the p-type electrode 2 of the optical semiconductor device is directed downward. When the forward-direction voltage is applied to the p-type electrode 2 and the n-type electrode 3, holes are supplied from the p-type InGaAs contact layer 6 to the active layer 4 through the p-type InP cladding layer 5, and electrons are supplied from the n-type InP substrate 1 to the active layer 4, in the active portions A. In a case where a semi-insulation material is used for the buried layer 12, a current hardly flows through the buried layer 12 having high resistivity. Therefore, the current can be efficiently injected into the active layer 4. However, the semi-insulation material used for the buried layer 12 is not always high in resistivity. In a case where Zn as a dopant material is diffused into the buried layer 12 from the p-type InGaAs contact layer 6 or the p-type InP cladding layer 5 adjacent during a wafer process, the resistivity is reduced, and a current path may occur in the buried layer 12. In contrast, in the passive portions B, the reverse-direction voltage is applied between the n-type InP layer 7 and the p-type InGaAs contact layer 6. Therefore, the current is blocked, and the current path to the buried layer 12 does not occur.

The present embodiment requires multiple times of crystal growth. However, the current can be efficiently injected into the active layer 4 as compared with Embodiment 1. In addition, as in Embodiment 1, it is possible to cut out a chip by cleavage at an optional passive portion B.

### Embodiment 3

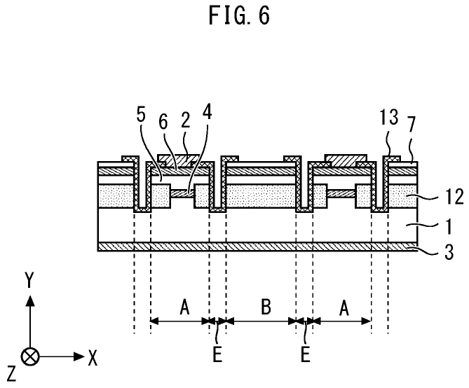

FIG. 6 is a cross-sectional view illustrating an optical semiconductor device according to Embodiment 3. At portions between the active portions A and the respective passive portion B alternately arranged in the X direction, etching extends from the p-type InGaAs contact layer 6 up to the n-type InP substrate 1 below the buried layer 12, and groove portions E are accordingly formed. Each of the active portions A and the groove portions E adjacent thereto constitute a mesa structure. Inner surfaces of the groove portions E are covered with insulation films 13. Each of the insulation film 13 may protrude to the adjacent active portion A or the adjacent passive portion B. A width of each of the groove portions E is within a range from about 5 um to about 20 um, but may be greater than the range. The side surfaces of the groove portions E may be vertical, or may be gently inclined. A width of each of the active portions A is within 20 um in most cases, but may be greater than 20 um.

The other structure is similar to the structure in Embodiment 2. Note that the optical semiconductor device is not limited to the end-surface emission buried laser array, and similar effects can be achieved by an optical amplifier, an optical modulator, or the like as long as the optical semiconductor device is of a waveguide type.

Subsequently, a method of manufacturing the optical semiconductor device according to the present embodiment is described. Subsequent to the semiconductor crystal growth as in Embodiment 2, the n-type InP layer 7 is first removed using hydrochloric acid in regions corresponding to the active portions A, to expose the p-type InGaAs contact layer 6 below the n-type InP layer 7. Next, a mask having stripe-shaped openings extending in the direction is formed on the p-type InGaAs contact layer 6 and the n-type InP layer 7 as the outermost surface. The p-type InGaAs contact layer 6 or the n-type InP layer 7 is exposed in each of the openings. Thereafter, the exposed semiconductor layer is etched up to below the buried layer 12, to form the groove portions E.

Next, after the mask is removed, the insulation film 13 made of SiO₂ or SiN and having a thickness of 0.4 um is formed so as to cover the entire surface of the semiconductor layer. Thereafter, a mask having stripe-shaped openings extending in the direction is formed using a photoresist. Next, the insulation film 13 is etched to form insulation film openings for electrode contact on the active portions A and insulation film openings for cleavage on the passive portions B. Thereafter, the n-type electrode 3, the p-type electrode 2, and the like are formed in a manner similar to Embodiment 1. As a result, the optical semiconductor device according to the present embodiment is manufactured.

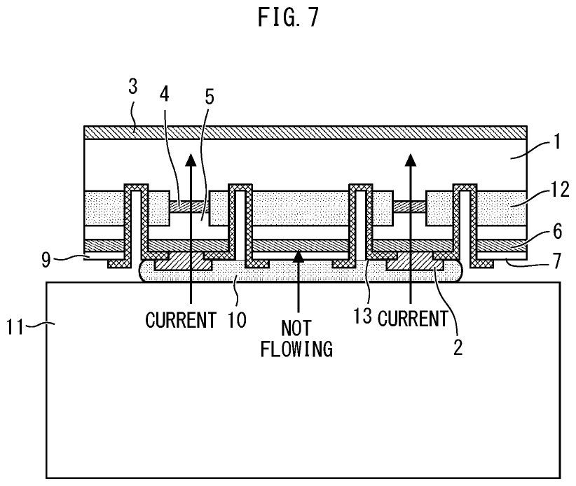

FIG. 7 is a cross-sectional view illustrating a state where the optical semiconductor device according to Embodiment 3 is junction-down mounted. The optical semiconductor device according to Embodiment 3 is junction-down mounted on the sub-mount 11 with the solder 10 while the p-type electrode 2 of the optical semiconductor device is directed downward. Providing the groove portions E makes it possible to reduce a parasitic capacitance of the device, which is therefore workable in high-speed modulation operation as compared with Embodiment 2. Even in a case where the solder 10 flows into the groove portions E, the insulation film 13 covering the groove portions E can prevent a reactive current path not passing through the active layer 4 from being generated. In addition, effects similar to the effects by Embodiment 2 can be achieved.

### Embodiment 4

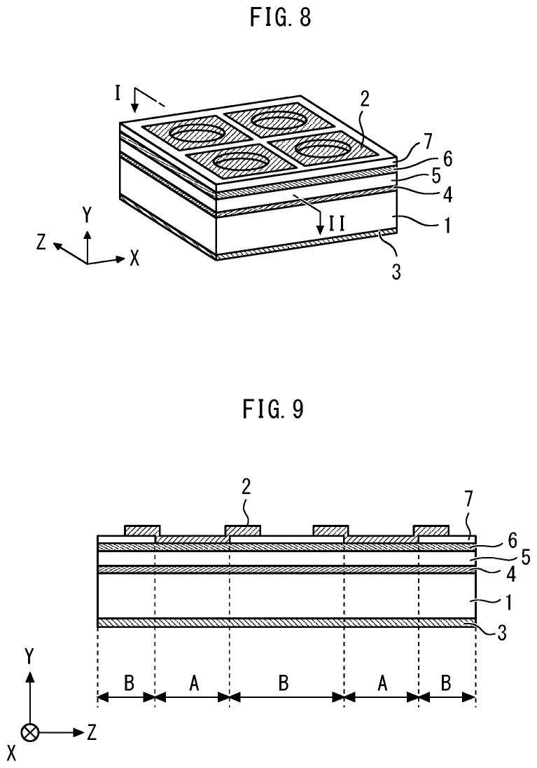

FIG. 8 is a perspective view illustrating an optical semiconductor device according to Embodiment 4. A plane parallel to a substrate surface is regarded as an XZ plane, and a stacking direction of semiconductor layers is regarded as a Y direction. A plurality of active portions A are provided in a matrix shape on the n-type InP substrate 1 in a planar view. In other words, the plurality of active portions A are arranged on the XZ plane to constitute a two-dimensional array structure. The passive portions B are provided on the n-type InP substrate 1 so as to surround four sides of each of the active portions A in a planar view. In other words, side surfaces of the active portions A in the X direction and the Z direction are surrounded by the passive portions B. The p-type electrode 2 is provided on the active portions A and the passive portions B. The n-type electrode 3 is provided on the lower surface of the n-type InP substrate 1. In the present embodiment, a surface-emission LED is described as an example of the two-dimensional array structure; however, similar effects can be achieved by a surface-emission laser, an optical amplifier, an optical modulator, or the like as long as the optical semiconductor device is a surface optical semiconductor device.

FIG. 9 is a cross-sectional view taken along line I-II in FIG. 8. Each of the active portions A includes the active layer 4, the p-type InP cladding layer 5, and the p-type InGaAs contact layer 6 that are stacked in order on the n-type InP substrate 1. The p-type InGaAs contact layer 6 as the outermost surface in the active portions A is in contact with the p-type electrode 2. The p-type InGaAs contact layer 6 exposed as the outermost surface is not limited to a circular shape, and may have an optional shape such as a rectangular shape. Further, it is unnecessary for the p-type electrode 2 and the n-type electrode 3 to cover the entire surface of the semiconductor layer, and the p-type electrode 2 and the n-type electrode 3 each may partially include a hole for allowing light to pass therethrough.

Each of the passive portions B includes the active layer 4, the p-type InP cladding layer 5, the p-type InGaAs contact layer 6, and the n-type InP layer 7 that are stacked in order on the n-type InP substrate 1. The passive portions B are different from the active portions A in that the n-type InP layer 7 is provided between the p-type InGaAs contact layer 6 and the p-type electrode 2. The p-type electrode 2 and the n-type electrode 3 in each of the active portions A may be within a range of each of the active portions A, or may protrude to the adjacent passive portions B.

Subsequently, a method of manufacturing the optical semiconductor device according to the present embodiment is described. First, the active layer 4, the p-type InP cladding layer 5, the p-type InGaAs contact layer 6, and the n-type InP layer 7 are crystal-grown in order on the n-type InP substrate 1. Next, a photoresist is formed on the n-type InP layer 7 as the outermost surface. Next, openings each having an optional shape such as a circular shape and a rectangular shape are formed in the photoresist in regions corresponding to the active portions A. Each of the openings has a diameter of 0.1 um or more in a case of the circular shape; however, the width of each of the openings is not limited to the range.

Thereafter, the n-type InP layer 7 exposed from the openings of the photoresist is removed using hydrochloric acid to expose the p-type InGaAs contact layer 6 below the n-type InP layer 7. After the photoresist is removed, films of a metal simple substance containing Au, Pt, Zn, Ge, Ni, Ti, and the like, transparent electroconductive films, or films of a mixture of these metals are formed on the p-type InGaAs contact layer 6 and below the n-type InP substrate 1, to form the p-type electrode 2 and the n-type electrode 3. Finally, the passive portions B in which the n-type InP layer 7 is exposed as the outermost surface are scribed and cleaved in the direction and a [1-10] direction by a diamond cutter, to manufacture a two-dimensional LED array in which an optional number of LEDs are arranged.

In a case where the optical semiconductor device according to the present embodiment is junction-down mounted, effects similar to the effects by Embodiment 1 can be achieved. Further, the light generated in the active layer 4 in the active portions A by current injection can be taken out through the n-type electrode 3 in the Y direction. At this time, when a hole is formed in a part of the n-type electrode 3 to expose the n-type InP substrate 1 or a transparent electroconductive film is combined as an electrode material, the light can be efficiently taken out.

### Embodiment 5

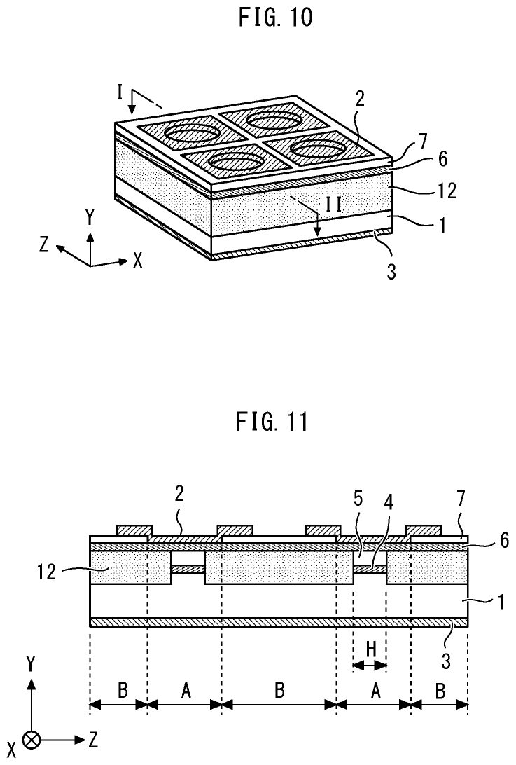

FIG. 10 is a perspective view illustrating an optical semiconductor device according to Embodiment 5. FIG. 11 is a cross-sectional view taken along line I-II in FIG. 10. Etching extends from the p-type InP cladding layer 5 up to below the active layer 4, and micropillar structures H are accordingly provided. The buried layer 12 is provided so as to cover side surfaces of the micropillar structures H up to a position higher than the active layer 4. The buried layer 12 is made of a semi-insulation material such as InP doped with Ru or Fe, but may be obtained by combining a plurality of semiconductor layers different in carrier concentration or polarity. The p-type InGaAs contact layer 6 is provided on the micropillar structures H and the buried layer 12. Each of the passive portions B includes the buried layer 12, the p-type InGaAs contact layer 6, and the n-type InP layer 7 that are stacked in order on the n-type InP substrate 1. A p-type InP layer may be provided between the p-type InP cladding layer 5 as the outermost surface in the ridge structures D and the p-type InGaAs contact layer 6 and between the buried layer 12 and the p-type InGaAs contact layer 6. The other structure is similar to the structure in Embodiment 4.

Subsequently, a method of manufacturing the optical semiconductor device according to the present embodiment is described. First, the active layer 4 and the p-type InP cladding layer 5 are crystal-grown in order on the n-type InP substrate 1. Thereafter, a circular or polygonal mask pattern is formed on the p-type InP cladding layer 5. Thereafter, etching is performed up to below the active layer 4 to form micropillar structures H. Next, the buried layer 12 is grown to cover the side surfaces of the micropillar structures H up to above the active layer 4. After the mask is removed, the p-type InGaAs contact layer 6 and the n-type InP layer 7 are grown on the buried layer 12 and the p-type InP cladding layer 5 as the outermost surface of the ridge structures. The crystal grown step is thus completed. A subsequent step is similar to the step in Embodiment 4.

The present embodiment can achieve the effects by the two-dimensional array structure in Embodiment 4 and the effects by the buried layer 12 in Embodiment 2.

Note that, in each of Embodiments 1 to 5, the polarities of the substrate and the semiconductor layers may be inverted. More specifically, the n-type InP substrate 1 and the n-type InP layer 7 may be changed to a p-type, and the p-type InP cladding layer 5 and the p-type InGaAs contact layer 6 may be changed to an n-type. In this case, similar laser array can also be fabricated and operated.

### REFERENCE SIGNS LIST

1 n-type InP substrate; 2 p-type electrode; 4 active layer; 5 p-type InP cladding layer; 6 p-type InGaAs contact layer; 7 n-type InP layer; 8 front end surface; 9 rear end surface; 12 buried layer; 13 insulation film; A active portion; B passive portion; D ridge structure; E groove portion; H micropillar structure

1. An optical semiconductor device comprising:
a semiconductor substrate of a first conductive type;
active portions and passive portions alternately arranged along a first direction on the semiconductor substrate; and
an electrode provided on the active portion,
wherein the active portion includes an active layer, a second conductive type cladding layer, and a second conductive type contact layer that are stacked in order on the semiconductor substrate,
the active portion has a resonator structure sandwiched between a front end surface and a rear end surface in a second direction perpendicular to the first direction,
the second conductive type contact layer in the active portion is in contact with the electrode, and
the passive portion includes the second conductive type contact layer and a first conductive type layer provided on the second conductive type contact layer.

2. The optical semiconductor device according to claim 1, wherein a ridge structure extending in the second direction is provided by etching from the second conductive type cladding layer to below the active layer,
a buried layer is provided so as to cover side surfaces of the ridge structure up to a position higher than the active layer,
the second conductive type contact layer is provided on the ridge structure and the buried layer, and
the passive portion includes the buried layer, the second conductive type contact layer, and the first conductive type layer that are stacked in order on the semiconductor substrate.

3. The optical semiconductor device according to claim 2, wherein a groove portion is provided by etching from the second conductive type contact layer to below the buried layer between the active portion and the passive portion, and
the groove portion is covered with an insulation film.

4. An optical semiconductor device comprising:
a semiconductor substrate of a first conductive type;
a plurality of active portions provided in a matrix shape on the semiconductor substrate in a planar view;
passive portions provided on the semiconductor substrate so as to surround four sides of each of the active portions in a planar view; and
an electrode provided on the active portion,
wherein the active portion includes an active layer, a second conductive type cladding layer, and a second conductive type contact layer that are stacked in order on the semiconductor substrate,
the second conductive type contact layer in the active portion is in contact with the electrode, and
the passive portion includes the second conductive type contact layer and a first conductive type layer provided on the second conductive type contact layer.

5. The optical semiconductor device according to claim 4, wherein a micropillar structure is provided by etching from the second conductive type cladding layer to below the active layer,
a buried layer is provided so as to cover side surfaces of the micropillar structure up to a position higher than the active layer,
the second conductive type contact layer is provided on the micropillar structure and the buried layer, and
the passive portion includes the buried layer, the second conductive type contact layer, and the first conductive type layer that are stacked in order on the semiconductor substrate.

6. The optical semiconductor device according to claim 1, wherein the semiconductor substrate, the second conductive type cladding layer, and the first conductive type layer are made of InP,
the second conductive type contact layer is made of InGaAs.

7. The optical semiconductor device according to claim 1, wherein the first conductive type layer has a thickness of 50 nm or more.

8. The optical semiconductor device according to claim 4 wherein the semiconductor substrate, the second conductive type cladding layer, and the first conductive type layer are made of InP,
the second conductive type contact layer is made of InGaAs.

9. The optical semiconductor device according to claim 4, wherein the first conductive type layer has a thickness of 50 nm or more.
